(19) United States
(12) Patent Application Publication
(10) Pub. No.: US 2025/0007236 A1
(43) Pub. Date: Jan. 2, 2025

(54) LIGHT EMITTING DEVICE AND DISTANCE MEASURING DEVICE

(71) Applicant: SONY SEMICONDUCTOR SOLUTIONS CORPORATION, KANAGAWA (JP)

(72) Inventors: MASAYA NAGATA, KANAGAWA (JP); HIROSHI ISOBE, KANAGAWA (JP)

(21) Appl. No.: 18/705,357

(22) PCT Filed: Oct. 17, 2022
(86) PCT No.: PCT/JP2022/038533

§ 371 Date: Apr. 26, 2024

(30) Foreign Application Priority Data
Nov. 5, 2021 (JP) 2021-181132

(51) Int. Cl. H01S 5/02; H01S 5/0233; H01S 5/0237; H01S 5/042; H01S 5/183

(52) U.S. Cl. CPC H01S 5/0216; H01S 5/0233; H01S 5/0237; H01S 5/042; H01S 5/18361

(57) ABSTRACT

To prevent peeling of a bonding portion between a first substrate having a light emitting element and a second substrate such as an LDD substrate. A light emitting device includes: a first substrate having a light emitting element; and a second substrate bonded to a surface side opposite to a light emitting surface of the light emitting element, in which the first substrate includes: a first conductive layer laminated on the opposite surface side of the light emitting element; a second conductive layer that is laminated on the first conductive layer and reflects light emitted from the light emitting element to the opposite surface side; a third conductive layer laminated on the second conductive layer and bonded to the second substrate via a bonding member; and an insulating layer laminated on the third conductive layer so as to cover at least end portions of the second conductive layer and the third conductive layer laminated.

### TECHNICAL FIELD

The present disclosure relates to a light emitting device and a distance measuring device.

### BACKGROUND ART

In recent years, a surface emitting laser such as a vertical cavity surface emitting laser (VCSEL) has attracted attention as a type of semiconductor laser (see Patent Document 1). The VCSEL has excellent features of low power consumption, low cost, mass production, and easy two-dimensional arraying. In particular, since a back-illuminated VCSEL does not require wire bonding and can be directly connected to a laser diode driver (LDD) substrate, a single photon avalanche diode (SPAD) substrate, or the like, downsizing and multi-functionalization can be easily realized.

### CITATION LIST

### Patent Document

Patent Document 1: Japanese Unexamined Patent Application Publication No. 2014-529199

### SUMMARY OF THE INVENTION

### Problems to be Solved by the Invention

When a VCSEL chip is bonded to the LDD substrate or the like, a method can be adopted in which a bonding member such as solder is formed on a pad on an upper surface of a light emitting element having a mesa structure formed on the VCSEL chip, and then the LDD substrate or the like is bonded.

More specifically, it is conceivable to form solder on an upper surface of a pad electrode disposed on the light emitting element and bond the pad electrode to the LDD substrate or the like. The pad electrode is covered with an insulating layer.

However, when the pad electrode or a reflection electrode under the pad electrode is cracked or there is a gap between the end surface of the pad electrode or the like and the insulating layer, solder enters the crack or the gap, and there is a possibility that the solder is eutectic with gold which is a material of the pad electrode or the like, the volume is expanded, and the pad electrode or the reflection electrode is peeled off.

In particular, since each light emitting element in the VCSEL chip has a mesa structure and the pad area of each light emitting element is small, peeling is likely to occur.

Therefore, the present disclosure provides a light emitting device and a distance measuring device capable of preventing peeling of a bonding portion between a first substrate having a light emitting element and a second substrate such as an LDD

### Solutions to Problems

In order to solve the above problems, according to the present disclosure, there is provided a light emitting device including:
a first substrate having a light emitting element; and
a second substrate bonded to a surface side opposite to a light emitting surface of the light emitting element,
in which the first substrate includes:
a first conductive layer laminated on the opposite surface side of the light emitting element;
a second conductive layer that is laminated on the first conductive layer and reflects light emitted from the light emitting element to the opposite surface side;
a third conductive layer laminated on the second conductive layer and bonded to the second substrate via a bonding member; and
an insulating layer laminated on the third conductive layer so as to cover at least end portions of the second conductive layer and the third conductive layer laminated.

The insulating layer may be disposed so as to cover at least a part of an upper surface of the third conductive layer from the end portion.

A surface of the third conductive layer facing the second substrate may include:
a first region in contact with the bonding member; and
a second region disposed outside the first region and covered with the insulating layer.

The second region may be disposed from a position overlapping the first conductive layer to the end portion when viewed from the lamination direction.

The second region may be disposed from a position closer to a center portion side of a surface of the third conductive layer facing the second substrate than a position overlapping the first conductive layer when viewed from the lamination direction to the end portion.

A thickness of the insulating layer in the second region may be substantially uniform from a center portion side to an end portion side of a surface of the third conductive layer facing the second substrate.

A thickness of the insulating layer in the second region may change from a center portion side to an end portion side of a surface of the third conductive layer facing the second substrate.

A thickness of the insulating layer in the second region may be thicker on an end portion side than on a center portion side of a surface of the third conductive layer facing the second substrate.

The second substrate may include a drive circuit configured to control light emission of the light emitting element.

The light emitting device may further include a light receiving unit.

The second substrate may include a voltage supply unit configured to supply a predetermined voltage having a fixed voltage level to the light emitting element.

The first conductive layer may be disposed in an annular shape so as to surround at least a part of a region through which light emitted by the light emitting element passes,
the second conductive layer may be disposed so as to cover an entire region of the first conductive layer including a region through which the light passes, and
the third conductive layer may be disposed so as to cover an entire region of the second conductive layer.

The first conductive layer may be interrupted at least at one location in an annular direction.

The light emitting element may be a mesa structure, and
the first substrate may include a plurality of the light emitting elements.

The first conductive layer may be a contact electrode electrically connected to an electrode on the opposite surface side of the light emitting element,
the second conductive layer may be a reflection electrode that reflects light emitted from the light emitting element to the opposite surface side, and
the third conductive layer may be a pad electrode that bonds the first substrate to the second substrate via the bonding member.

According to the present disclosure, there is provided a light emitting device including:
a first substrate having a light emitting element; and
a second substrate bonded to a surface side opposite to a light emitting surface of the light emitting element,
in which the first substrate includes:
a reflection layer laminated on the opposite surface side of the light emitting element;
a first conductive layer laminated around the reflection layer on the opposite surface side of the light emitting element;
a second conductive layer that is laminated on the reflection layer and the first conductive layer and reflects light emitted from the light emitting element to the opposite surface side;
a third conductive layer laminated on the second conductive layer and bonded to the second substrate via a bonding member; and
an insulating layer laminated on the third conductive layer so as to overlap at least a part of the reflection layer when viewed in plan from a normal direction of the opposite surface of the light emitting element.

The insulating layer may be laminated on the third conductive layer so as to overlap an entire region on an outer peripheral side of the reflection layer when viewed in plan from a normal direction of the opposite surface of the light emitting element.

The reflection layer may have at least one protrusion protruding outward from an outer peripheral portion of the reflection layer in plan view from a normal direction of the opposite surface of the light emitting element, and
the insulating layer may be laminated on the third conductive layer so as to overlap the protrusion when viewed in plan from the normal direction of the opposite surface of the light emitting element.

According to the present disclosure, there is provided a distance measuring device including:
a light emitting device including a light emitting element;
a light receiving element; and
a distance measuring unit configured to measure a distance to an object on a basis of a light emitting signal of the light emitting element and a light receiving signal of the light receiving element when the light emitting signal is reflected by the object and received by the light receiving element,
in which the light emitting device includes:
a first substrate including the light emitting element; and
a second substrate bonded to a surface side opposite to a light emitting surface of the light emitting element,
the first substrate includes:
a first conductive layer laminated on the opposite surface side of the light emitting element;
a second conductive layer that is laminated on the first conductive layer and reflects light emitted from the light emitting element to the opposite surface side;
a third conductive layer laminated on the second conductive layer and bonded to the second substrate via a bonding member; and
an insulating layer laminated on the third conductive layer so as to cover at least an end portion of the third conductive layer.

### BRIEF DESCRIPTION OF DRAWINGS

FIG. 1 is a schematic cross-sectional view showing a schematic configuration of a light emitting device according to an embodiment.

FIG. 2 is a cross-sectional view showing structures of an LDD substrate and an LD chip of the light emitting device of FIG. 1 in more detail.

FIG. 3 is a cross-sectional view showing a bonding portion between an LDD substrate and an LD chip in detail.

FIG. 4A is a cross-sectional view of the light emitting device according to the present embodiment.

FIG. 4B is a plan view of the light emitting device of FIG. 4A.

FIG. 5A is a view showing a state in which a crack is generated in a laminated reflection electrode and pad electrode.

FIG. 5B is a cross-sectional view illustrating a state in which solder enters the inside of the pad electrode and the reflection electrode.

FIG. 6A is a cross-sectional view of a light emitting device according to a first modification of FIG. 4A.

FIG. 6B is a plan view of the light emitting device of FIG. 6A.

FIG. 7A is a cross-sectional view of the light emitting device according to the first modification of FIG. 4A.

FIG. 7B is a plan view of the light emitting device of FIG. 7A.

FIG. 8A is a plan view of a contact electrode in a light emitting device according to a fourth modification.

FIG. 8B is a plan view of a contact electrode in a light emitting device according to a fifth modification.

FIG. 9A is a process cross-sectional view showing a process of manufacturing an LDD substrate according to the present embodiment.

FIG. 9B is a process cross-sectional view subsequent to FIG. 9A.

FIG. 9C is a process cross-sectional view subsequent to FIG. 9B.

FIG. 9D is a process cross-sectional view subsequent to FIG. 9C.

FIG. 9E is a process cross-sectional view subsequent to FIG. 9D.

FIG. 9F is a process cross-sectional view subsequent to FIG. 9E.

FIG. 9G is a process cross-sectional view subsequent to FIG. 9F.

FIG. 9H is a process cross-sectional view subsequent to FIG. 9G.

FIG. 10A is a process cross-sectional view illustrating a process of manufacturing an LD chip according to the present embodiment.

FIG. 10B is a process cross-sectional view subsequent to FIG. 10A.

FIG. 10C is a process cross-sectional view subsequent to FIG. 10B.

FIG. 11A is a manufacturing process view showing in detail a process of bonding each divided light emitting element to an LDD substrate.

FIG. 11B is a process cross-sectional view subsequent to FIG. 11A.

FIG. 11C is a process cross-sectional view subsequent to FIG. 11B.

FIG. 12 is a cross-sectional view of a light emitting device according to a second embodiment.

FIG. 13 is a plan view of a surface opposite to a light emitting surface of the light emitting device of FIG. 12 as seen in plan view from a normal direction.

FIG. 14 is a cross-sectional view of a light emitting device according to a modification of the second embodiment.

FIG. 15 is a plan view of the light emitting device according to the modification of the second embodiment.

FIG. 16 is a cross-sectional view of a light emitting device according to a comparative example.

FIG. 17 is a cross-sectional view of a ToF sensor.

FIG. 18 is a view illustrating a configuration example of a distance measuring device as an implementation example of the light emitting device according to the present embodiment.

FIG. 19A is an explanatory view of an STL method.

FIG. 19B is an explanatory view of a distance measurement principle of the STL method.

FIG. 20 is a block diagram illustrating an example of a schematic configuration of a vehicle control system.

FIG. 21 is an explanatory view illustrating an example of installation positions of an outside-vehicle information detecting section and an imaging section.

### MODE FOR CARRYING OUT THE INVENTION

Hereinafter, embodiments of a light emitting device and a distance measuring device will be described with reference to the drawings. Hereinafter, the main components of the light emitting device and the distance measuring device will be mainly described, but the light emitting device and the distance measuring device may have components and functions that are not shown or described. The following description does not exclude components and functions that are not shown or described.

### First Embodiment

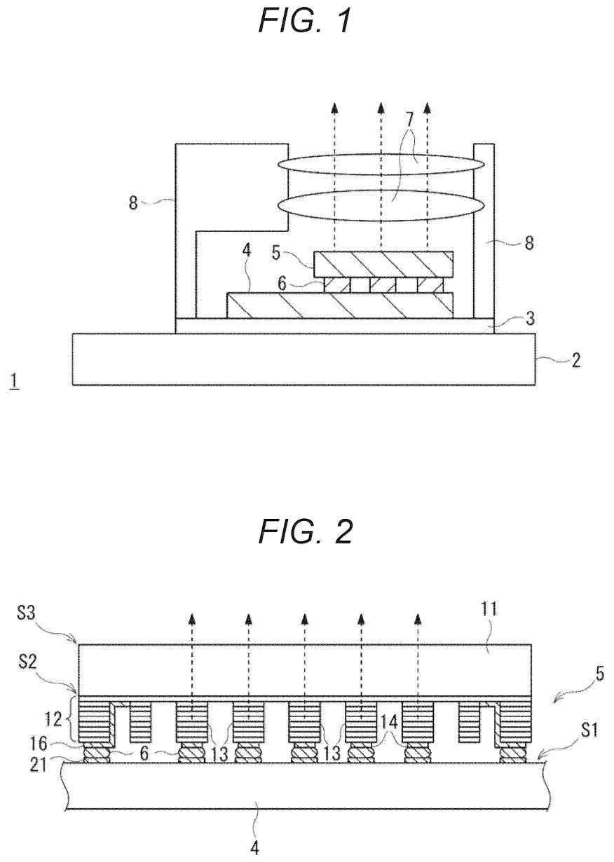

FIG. 1 is a schematic cross-sectional view illustrating a schematic configuration of a light emitting device 1 according to a first embodiment. As shown in FIG. 1, in the light emitting device 1 according to the present embodiment, an LDD substrate (first substrate) 4 is disposed on a mounting substrate 2 via a heat dissipation substrate 3, and a laser diode (LD) chip (second substrate) 5 is disposed on the LDD substrate 4. The LDD substrate 4 and the LD chip 5 are bonded by a bonding layer 6 containing solder. The LDD substrate 4 outputs a drive signal for driving a light emitting element in the LD chip 5 via the bonding layer 6. The LD chip 5 includes the light emitting element. The light emitting element emits laser light in a predetermined wavelength band in response to a drive signal from the LDD substrate 4. The laser beam emitted from the LD chip 5 is emitted to the outside via a correction lens 7. The correction lens 7 is held by a lens holding portion 8. Note that, since the correction lens 7 is not an essential member, it may be omitted.

FIG. 2 is a cross-sectional view showing the structures of the LDD substrate 4 and the LD chip 5 of the light emitting device 1 of FIG. 1 in more detail. The LD chip 5 includes a substrate 11, a laminated film 12, a plurality of light emitting elements 13 formed using the laminated film 12, a plurality of anode electrodes 14, and a cathode electrode 16.

The substrate 11 of the LD chip 5 is a substrate made of a compound semiconductor such as GaAs (gallium arsenide). The surface of the substrate 11 facing the LDD substrate 4 is a front surface S2, and the laser light is emitted from a back surface S3 side of the substrate 11. The laminated film 12 includes a first multilayer film reflector, a first spacer layer, an active layer, a second spacer layer, a second multilayer film reflector, and the like, causes laser light generated in the active layer to resonate between the first multilayer film reflector and the second multilayer film reflector to improve light intensity, and emits the laser light from the back surface S3 side of the substrate. As described above, the LD chip 5 of FIG. 2 is a back-illuminated type. In the present specification, the light emitting element 13 having the layer configuration as shown in FIG. 2 is referred to as a VCSEL structure.

The plurality of light emitting elements 13 have a mesa structure formed by processing the laminated film 12 into a mesa shape. When viewed from the substrate 11 side, an anode electrode (second pad) 14 is disposed on the upper surface of each light emitting element 13. Similarly, when viewed from the substrate 11 side, the cathode electrode 16 is disposed on the upper surface and the side surface of the laminated film 12 disposed on the end portion side of the LD chip 5. The cathode electrode 16 is also disposed on the lowermost layer side of the laminated film 12 of the plurality of light emitting elements 13 when viewed from the substrate 11 side. In FIG. 2, the arrangement of the anode electrode 14 and the cathode electrode 16 may be reversed. In FIG. 2, the common electrode is the cathode electrode 16, but the common electrode may be the anode electrode 14, and the cathode electrode 16 may be provided in each mesa portion.

The LDD substrate 4 includes a plurality of pads 21 for supplying a drive signal to the plurality of light emitting elements 13 of the LD chip 5. The bonding layer 6 is disposed on these pads 21 as described later, and the pads 21 of the LDD substrate 4 and the corresponding pads of the anode electrode 14 of the LD chip 5 are bonded via the bonding layer 6. Hereinafter, the pad of the LDD substrate 4 is referred to as a first pad 21, and the pad of the anode electrode 14 of the LD chip 5 is referred to as a second pad 14.

The LDD substrate 4 may include a drive circuit that generates a drive signal. In this case, the LDD substrate 4 performs active driving. Alternatively, the LDD substrate 4 may supply a voltage corresponding to a drive signal generated by an external drive circuit to the pads 21. In this case, the LDD substrate 4 performs passive driving.

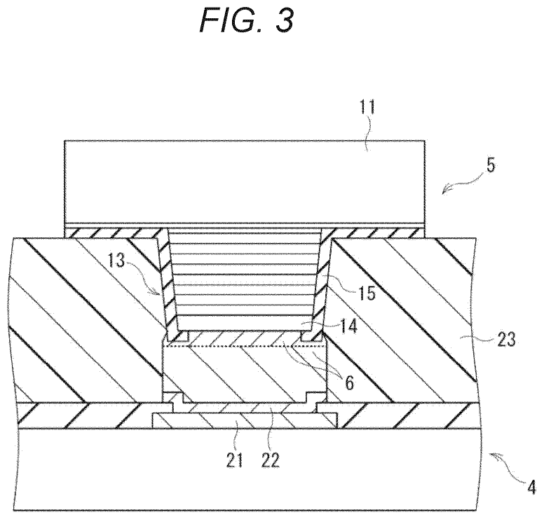

FIG. 3 is a cross-sectional view illustrating a bonding portion between the LDD substrate 4 and the LD chip 5 in detail. In the LD chip 5, after the plurality of light emitting elements 13 are formed on the substrate 11 and the anode electrode 14 is formed on the upper surface of each of the light emitting elements 13, the light emitting elements 13 are singulated by using one or a plurality of light emitting elements 13 as a unit. FIG. 3 shows an example in which the LD chip 5 including the singulated light emitting elements 13 is bonded to the LDD substrate 4.

The LDD substrate 4 shown in FIG. 3 includes the first pad 21 to which a drive signal is output, a third conductive layer 22 disposed on the first pad 21, and a bonding layer 6 disposed on the third conductive layer 22. The bonding layer 6 is a laminated film containing a solder material or the like. The LD chip 5 of FIG. 3 includes the light emitting element 13 having a mesa structure, the second pad 14, and an insulating layer 15 disposed around the second pad 14. The second pad 14 is disposed to face the first pad 21 and is bonded to the bonding layer 6. That is, the first pad 21 and the second pad 14 are bonded via the bonding layer 6.

As described later, the second pad 14 includes a contact electrode, a reflection electrode, and a pad electrode, but the second pad 14 is shown in a simplified manner in FIG. 3. Further, as will be described later, the present embodiment has a feature in an arrangement place of the insulating layer 15, but the insulating layer 15 is shown in a simplified manner in FIG. 3.

An underfill layer 23 is injected into a gap between the LDD substrate 4 and the LD chip 5. Accordingly, a bonding portion between the first pad 21 and the second pad 14 can be protected, and peeling or the like can be prevented. As will be described later, it is necessary to select the material of the underfill layer 23 and the like so as not to cause a defect called bleeding in which the underfill layer 23 crawls up to the side surface side of the LD chip 5.

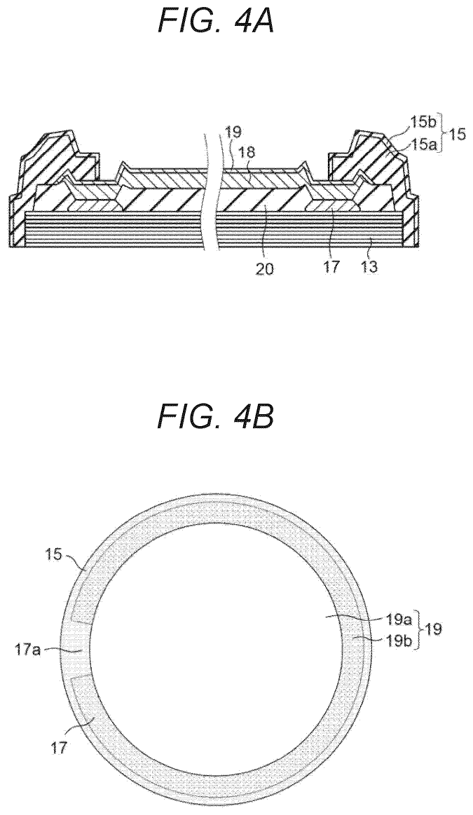

FIG. 4A is a cross-sectional view of the light emitting device 1 according to the first embodiment, and FIG. 4B is a plan view of the light emitting device 1 of FIG. 4A. FIG. 4A shows a cross-sectional structure of the light emitting element 13 disposed in a direction opposite to FIG. 3. The bottom surface of FIG. 4A is a light emitting surface.

As described above, the second pad 14 of FIG. 3 includes a contact electrode 17, a reflection electrode 18, and a pad electrode 19 of FIG. 4A. The contact electrode 17 is a first conductive layer laminated on the light emitting element 13 on a surface side opposite to the light emitting surface of the light emitting element 13. The reflection electrode 18 is a second conductive layer that is laminated on the contact electrode 17 and reflects light emitted to the surface side opposite to the light emitting surface of the light emitting element 13. The pad electrode 19 is a third conductive layer laminated on the reflection electrode 18 and bonded to the LDD substrate 4 via a bonding member (bonding layer) 6 such as solder.

As shown in FIG. 4A, the contact electrode 17 is laminated on the light emitting element 13. The contact electrode 17 is disposed in an annular shape so as to surround at least a part of a region through which light emitted from the light emitting element 13 passes. FIG. 4B shows an example in which a cutout portion 17a is formed in a part of the contact electrode 17, but the shape of the contact electrode 17 is arbitrary. The contact electrode 17 does not necessarily have an annular shape, and may have a rectangular annular shape. The contact electrode 17 is formed of, for example, an alloy of gold (Au) and germanium (Ge), nickel (Ni), gold (Au), or the like, or is formed in a stacked structure of nickel and gold.

An insulating layer 20 is disposed around the contact electrode 17. The insulating layer 20 is formed of, for example, silicon nitride (SiN) or a silicon oxide film (SiO₂).

The reflection electrode 18 is laminated on the contact electrode 17 and the insulating layer 20. The reflection electrode 18 is disposed in a planar shape from the outer peripheral side to the inner side of the contact electrode 17. The light emitting element 13 emits light downward in FIG. 4A, but some of the light travels upward. The light traveling upward is reflected by the reflection electrode 18 and travels downward. The reflection electrode 18 is formed of, for example, titanium (Ti), gold (Au), or the like, or is formed in a stacked structure of titanium and gold.

The pad electrode 19 is laminated on the reflection electrode 18. The pad electrode 19 is formed of, for example, titanium (Ti), gold (Au), or the like, or is formed in a stacked structure of titanium and gold. The pad electrode 19 is laminated so as to cover the entire region of the reflection electrode 18.

The insulating layer 15 is laminated on the pad electrode 19. The insulating layer 15 is formed of, for example, silicon nitride (SiN). The insulating layer 15 is laminated so as to cover at least the end surfaces of the laminated pad electrode 19 and reflection electrode 18, and this is one of the features of the present embodiment. By laminating the insulating layer 15 so as to cover the end surfaces of the pad electrode 19 and the reflection electrode 18, it is possible to prevent solder from entering from the end surfaces, and there is no possibility that the solder is eutectic with gold (Au) or the like and expands to peel off the pad electrode 19 and the reflection electrode 18.

In FIG. 4A, the insulating layer 15 has a two-layer structure. Both the layers may be formed of silicon nitride (SiN) or may be formed of materials different from each other. Hereinafter, the lower layer side of the insulating layer 15 having the two-layer structure is referred to as a first insulating layer 15a, and the upper layer side is referred to as a second insulating layer 15b. The first insulating layer 15a and the second insulating layer 15b in the insulating layer 15 of FIG. 4A have substantially the same area, and the positions of the end surfaces are also substantially the same. In the example of FIG. 4A, the film thickness of the first insulating layer 15a is thicker than the film thickness of the second insulating layer 15b, but the film thicknesses of the first insulating layer 15a and the second insulating layer 15b are arbitrary.

As shown in FIG. 4B, the upper surface of the pad electrode 19 has a first region 19a where the pad electrode 19 is exposed, and a second region 19b covered with the insulating layer 15. The first region 19a is disposed on the center side of the upper surface of the pad electrode 19, and the second region 19b is disposed on the outer peripheral side of the upper surface of the pad electrode 19. More specifically, the second region 19b is disposed from the position overlapping the contact electrode 17 to the end portion side of the pad electrode 19 when viewed from the lamination direction.

The bonding layer 6 such as solder as shown in FIG. 3 is attached to the first region 19a and bonded to the LDD substrate 4. As shown in FIG. 4B, in the light emitting device of FIG. 4A, since the ratio of the area of the first region 19a is large, the bonding strength with the LDD substrate 4 can be increased.

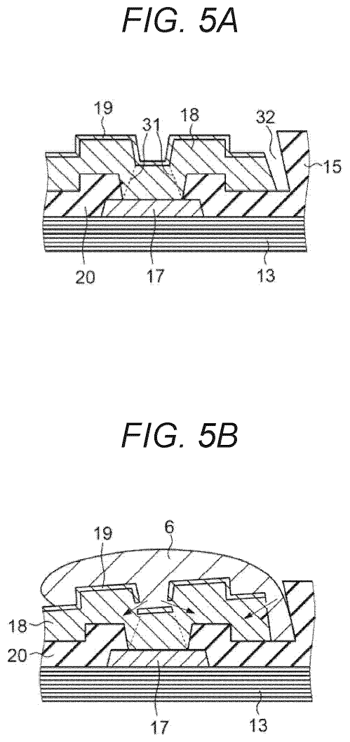

FIGS. 5A and 5B are views for explaining a phenomenon in which the pad electrode 19 and the reflection electrode 18 are peeled off. FIGS. 5A and 5B show a cross-sectional structure around the contact electrode 17. FIG. 5A shows a state in which a crack 31 is generated in the laminated reflection electrode 18 and pad electrode 19. The light emitting element 13 is processed into a mesa shape, and when the reflection electrode 18 and the pad electrode 19 are laminated thereon, the crack 31 is likely to occur at the stepped portion. In addition, in the example of FIG. 5A, the insulating layer 15 disposed around the pad electrode 19 and the reflection electrode 18 does not cover the end surfaces of the pad electrode 19 and the reflection electrode 18, and a gap 32 is generated between the end surfaces of the pad electrode 19 and the reflection electrode 18 and the insulating layer 15 on the outer side thereof.

When solder is attached onto the pad electrode 19 in a state where the crack 31 is generated, the solder enters the pad electrode 19 and the reflection electrode 18 from the crack 31, and is eutectic with gold (Au) and expands as shown in FIG. 5B. In addition, solder enters the pad electrode 19 and the reflection electrode 18 from the gap 32 between the end surfaces of the pad electrode 19 and the reflection electrode 18 and the insulating layer 15 therearound, and similarly, the solder is eutectic with gold (Au) and expands. When the pad electrode 19 and the reflection electrode 18 expand, they are easily peeled off.

In the light emitting device 1 of FIG. 4A, since the insulating layer 15 covers at least the end surfaces of the pad electrode 19 and the reflection electrode 18, there is no gap 32 as in FIG. 5A between the end surfaces of the pad electrode 19 and the reflection electrode 18 and the insulating layer 15. Therefore, there is no possibility that solder enters the pad electrode 19 and the reflection electrode 18 from the end surfaces of the pad electrode 19 and the reflection electrode 18, and peeling of the pad electrode 19 and the reflection electrode 18 can be prevented.

In the light emitting device 1 of FIG. 4A, the insulating layer 15 covers only the outer peripheral sides of the pad electrode 19 and the reflection electrode 18, and the area where the pad electrode 19 is exposed increases. Since the bonding layer 6 containing solder is attached to the upper surface of the pad electrode 19 and bonded to the LDD substrate 4, the bonding area with the LDD substrate 4 can be increased, and the pad electrode 19 and the reflection electrode 18 are less likely to be peeled off.

On the other hand, in the light emitting device 1 of FIG. 4A, when the crack 31 as shown in FIG. 5A is generated in the pad electrode 19 and the reflection electrode 18, there is a possibility that solder enters the pad electrode 19 and the reflection electrode 18 from the crack 31 to cause peeling.

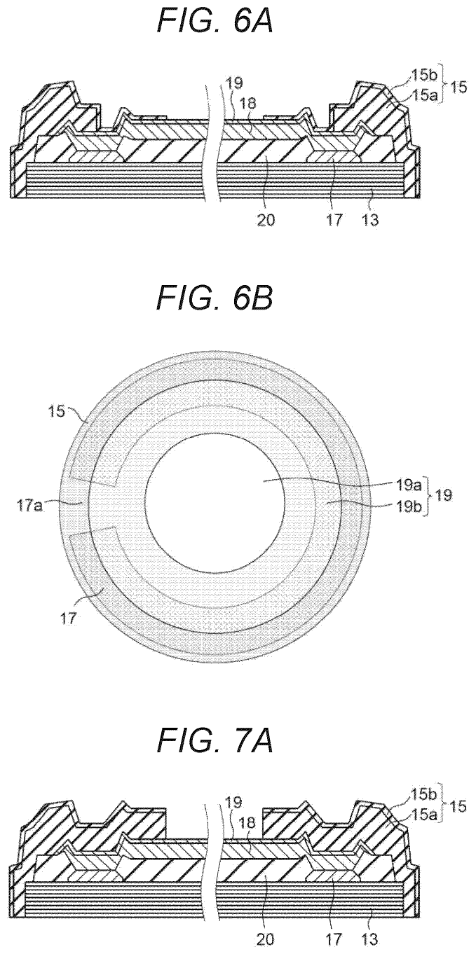

FIG. 6A is a cross-sectional view of a light emitting device 1 according to a first modification of FIG. 4A, and FIG. 6B is a plan view of the light emitting device 1 of FIG. 6A. An insulating layer 15 of FIG. 6A is different from the insulating layer 15 of FIG. 4A in arrangement place. The insulating layer 15 of FIG. 6A has a two-layer structure of a first insulating layer 15a and a second insulating layer 15b similarly to the insulating layer 15 of FIG. 4A. The first insulating layer 15a of FIG. 6A extends to the vicinity of the center of the contact electrode 17 as viewed from the lamination direction, similarly to the first insulating layer 15a of FIG. 4A. On the other hand, the second insulating layer 15b of FIG. 6A covers the pad electrode 19 to the inside of the inner peripheral end of the contact electrode 17 when viewed from the lamination direction. The second insulating layer 15b is thinner than the first insulating layer 15a.

An upper surface of the pad electrode 19 of FIG. 6A has a first region 19a where the pad electrode 19 is exposed, and a second region 19b covered with the insulating layer 15. The first region 19a is disposed on the center side of the upper surface of the pad electrode 19, and the second region 19b is disposed outside the first region 19a on the upper surface of the pad electrode 19. The first region 19a of FIG. 6A is smaller in area than the first region 19a of FIG. 4A. On the other hand, the second region 19b of FIG. 6A is larger in area than the second region 19b of FIG. 4A. More specifically, the second region 19b of FIG. 6A is disposed from a position closer to the center portion side of the upper surface of the pad electrode 19 than the position overlapping the contact electrode 17 when viewed from the lamination direction to the end portion of the pad electrode 19.

The thickness of the insulating layer 15 in the second region 19b changes from the center portion side to the end portion side of the surface of the pad electrode 19 facing the LDD substrate 4. More specifically, the thickness of the insulating layer 15 in the second region 19b is thicker on the end portion side than on the center portion side of the surface of the pad electrode 19 facing the LDD substrate 4. That is, only the second insulating layer 15b is disposed on the inner peripheral side of the second region 19b, the first insulating layer 15a and the second insulating layer 15b are disposed on the outer peripheral side of the second region 19b, and the insulating layer 15 is thicker on the outer peripheral side of the second region 19b than on the inner peripheral side.

As described above, in the light emitting element 13 of FIG. 6A, since the first region 19a where the pad electrode 19 is exposed is narrower than that of the light emitting device 1 of FIG. 4A, when the crack 31 is generated in the pad electrode 19 or the reflection electrode 18, the crack 31 is more likely to be covered with the insulating layer 15. Therefore, solder can be prevented from entering from the crack 31, and peeling of the pad electrode 19 and the reflection electrode 18 can be prevented.

As a result, even if the crack 31 is generated in the pad electrode 19 and the reflection electrode 18 around the contact electrode 17, the crack 31 can be covered with the insulating layer 15, and the entry of solder from the crack 31 can be suppressed as compared with FIG. 4A.

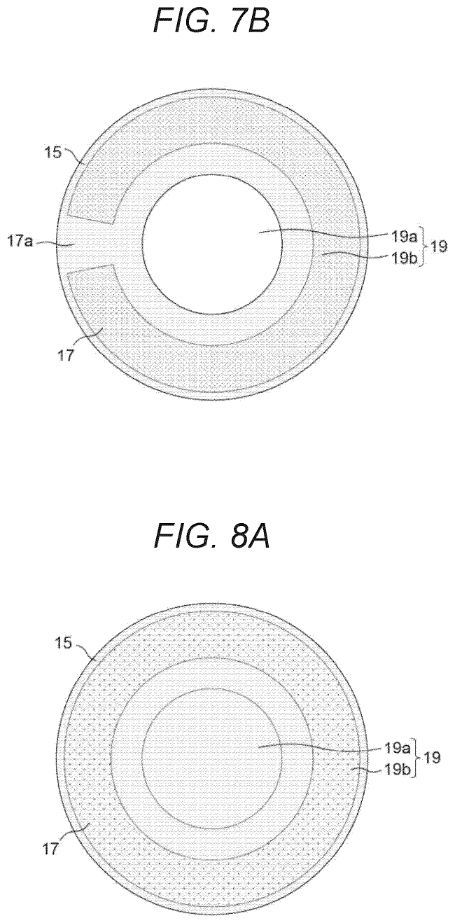

FIG. 7A is a cross-sectional view of a light emitting device 1 according to a first modification of FIG. 4A, and FIG. 7B is a plan view of the light emitting device 1 of FIG. 7A. An insulating layer 15 of FIG. 7A is different from the insulating layers 15 of FIGS. 4A and 6A in arrangement place. The insulating layer 15 of FIG. 7A has a two-layer structure of a first insulating layer 15a and a second insulating layer 15b similarly to the insulating layers 15 of FIGS. 4A and 6A, but both the first insulating layer 15a and the second insulating layer 15b are disposed to the inside of a contact electrode 17 as viewed from the lamination direction.

An upper surface of the pad electrode 19 of FIG. 7A has a first region 19a where the pad electrode 19 is exposed, and a second region 19b covered with the insulating layer 15. The first region 19a is disposed on the center side of the upper surface of the pad electrode 19, and the second region 19b is disposed on the outer peripheral side of the upper surface of the pad electrode 19. The first region 19a of FIG. 7 is smaller in area than the first region 19a of FIG. 4. On the other hand, the second region 19b of FIG. 7 is larger in area than the second region 19b of FIG. 4. More specifically, similarly to the second region 19b of FIG. 6, the second region 19b of FIG. 7 is disposed from a position closer to the center portion side of the upper surface of the pad electrode 19 than the position overlapping the contact electrode 17 when viewed from the lamination direction to the end portion of the pad electrode 19.

Both the first insulating layer 15a and the second insulating layer 15b of FIG. 7 are disposed on the pad electrode 19 to the inside of substantially the center of the contact electrode 17 when viewed from the lamination direction. As a result, even if the crack 31 is generated in the pad electrode 19 and the reflection electrode 18 around the contact electrode 17, the crack 31 can be covered with the insulating layer 15, and the entry of solder from the crack 31 can be suppressed as compared with FIG. 6.

A difference between FIG. 6A and FIG. 7A is whether only the thin second insulating layer 15b covers the center side of the pad electrode 19, or both the first insulating layer 15a and the second insulating layer 15b cover the center portion side of the pad electrode 19. Since the pad electrode 19 can be more firmly protected in FIG. 7A, the possibility of solder entering the crack 31 can be further avoided.

In both of the light emitting elements 13 of FIGS. 6A and 7A, the bonding area of the bonding layer 6 such as solder attached to the pad electrode 19 is narrower than that of the light emitting device 1 of FIG. 4A. Therefore, the bonding strength between the light emitting elements 13 of FIGS. 6A and 7A and the LDD substrate 4 is weaker than that of the light emitting device 1 of FIG. 4A.

As described above, in the light emitting elements 13 of FIGS. 4A, 6A, and 7A, the bonding strength with the LDD substrate 4 is the maximum in FIG. 4A, and the bonding strengths of the light emitting elements 13 of FIGS. 6A and 7A are about the same and weaker than the bonding strength of the light emitting device 1 of FIG. 4A. In addition, in the light emitting element 13 of FIGS. 4A, 6A, and 7A, from the viewpoint of preventing peeling due to entry of solder from the crack 31 generated in the pad electrode 19 and the reflection electrode 18, FIG. 7A is the most excellent, FIG. 6A is the second most excellent, and FIG. 4A is the most inferior.

Therefore, since the light emitting elements 13 of FIGS. 4A, 6A, and 7A have advantages and disadvantages, it is only required to determine to which position on the pad electrode 19 the insulating layer 15 is to be disposed in comprehensive consideration of the area of the second region 19b on the pad electrode 19, the likelihood of occurrence of the crack 31 in the pad electrode 19 and the reflection electrode 18, and the like.

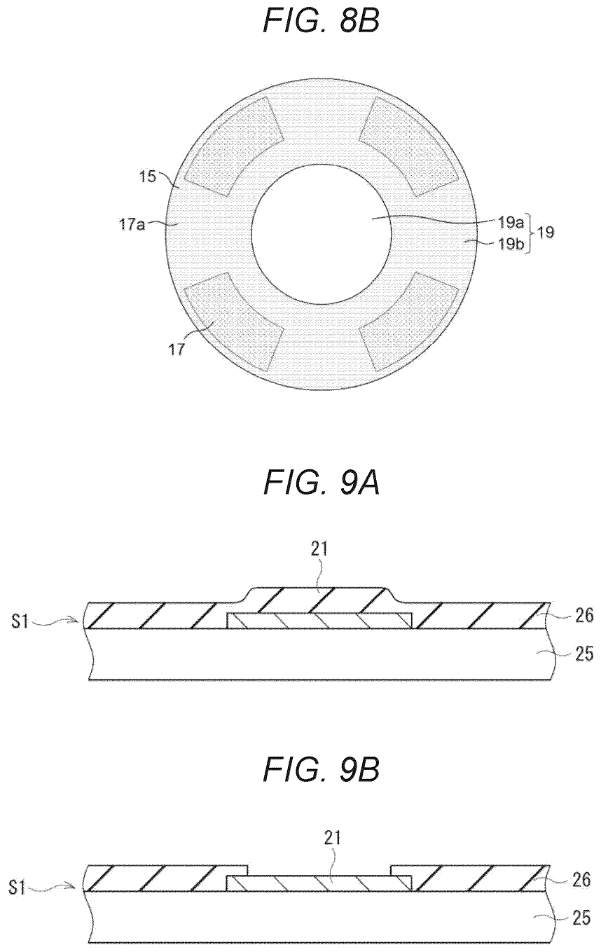

The contact electrode 17 in the light emitting element 13 shown in FIGS. 4A, 6A, and 7A has an annular shape partially having a cutout portion 17a, but may have other shapes. For example, FIG. 8A is a plan view of a contact electrode 17 in a light emitting device 1 according to a fourth modification, and FIG. 8B is a plan view of a contact electrode 17 in a light emitting device 1 according to a fifth modification. The contact electrode 17 of FIG. 8A has an annular shape without a cutout portion 17a. Further, the contact electrode 17 of FIG. 8B has an annular shape having a plurality of cutout portions 17a. In FIG. 8B, the size and number of cutout portions 17a are arbitrary. In addition, the sizes of the inner diameter and the outer diameter of the annular-shaped contact electrode 17 is arbitrary. Furthermore, the contact electrode 17 only needs to have a shape surrounding a path through which light from the light emitting element 13 passes, and does not necessarily need to have an annular shape, and may have a rectangular annular shape or a polygonal annular shape.

In FIGS. 1 to 8B described above, an example in which the light emitting element 13 having a mesa structure is bonded to the LDD substrate 4 via the bonding layer 6 such as solder has been described, but the substrate to which the light emitting element 13 is bonded is not necessarily limited to the LDD substrate 4. For example, as described above, the light emitting element 13 may be bonded to a passive substrate that supplies a voltage corresponding to a drive signal generated by an external drive circuit to the light emitting element 13. Furthermore, as will be described later, a light receiving element may be disposed on a substrate to which the light emitting element 13 is bonded. As a result, a ToF sensor in which the light emitting element 13 and the light receiving element are disposed on a common substrate is obtained.

As described above, in the light emitting device 1 according to the present embodiment, the contact electrode 17, the reflection electrode 18, and the pad electrode 19 are stacked on the surface side of the LD chip 5 opposite to the light emitting surface of the light emitting element 13, and the end surfaces of the reflection electrode 18 and the pad electrode 19 are covered with the insulating layer 15, so that solder does not enter the reflection electrode 18 and the pad electrode 19 from these end surfaces, and peeling of the reflection electrode 18 and the pad electrode 19 can be prevented.

In addition, by covering not only the end surfaces of the reflection electrode 18 and the pad electrode 19 but also the upper surface side of the pad electrode 19 with the insulating layer 15, even if the crack 31 occurs in the pad electrode 19 or the reflection electrode 18, solder can be prevented from entering from the crack 31.

### Process of Manufacturing LDD Substrate 4

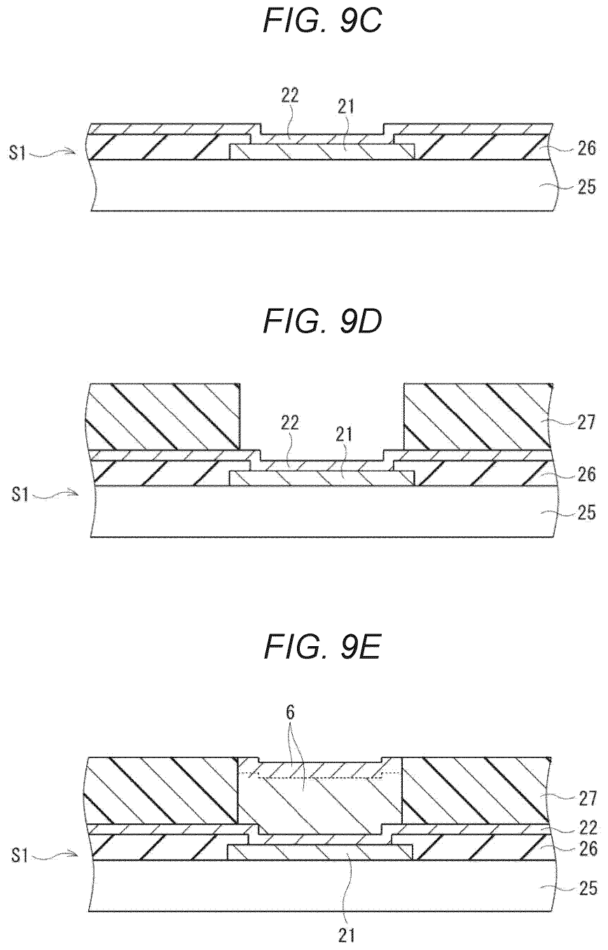

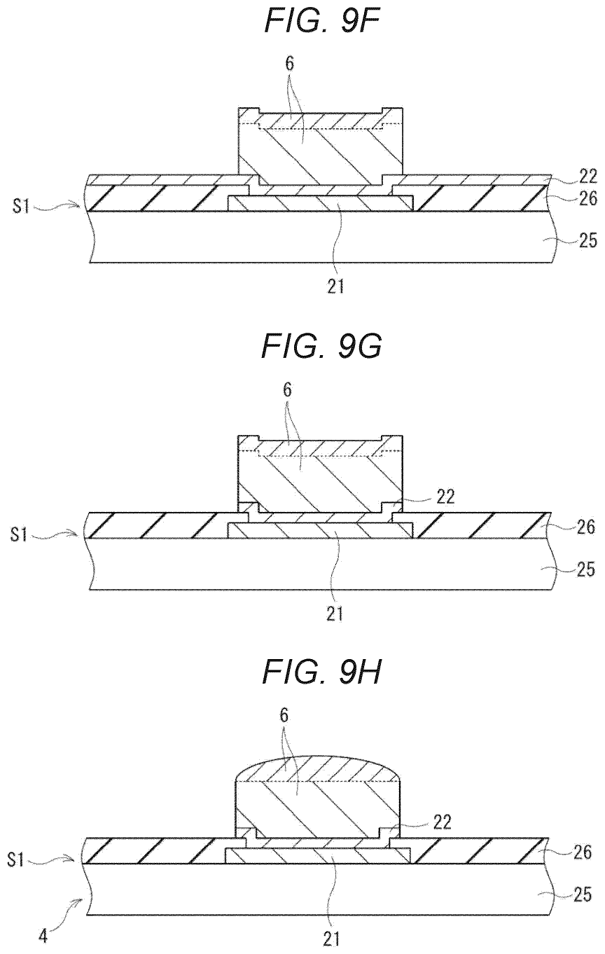

FIGS. 9A to 9H are process cross-sectional views illustrating the process of manufacturing the LDD substrate 4 according to the present embodiment. First, as shown in FIG. 9A, the first pad 21 is formed on the first surface S1 of the first substrate 25, and the insulating film 26 is formed on the first surface S1 so as to cover the first pad 21. The first substrate 25 is, for example, a silicon substrate. The insulating film 26 is provided to protect the first pad 21 and prevent a short circuit between the adjacent first pads 21. The insulating film 26 may be an organic insulating film or an inorganic insulating film. The material of the organic insulating film is, for example, polyimide or polymer. The material of the inorganic insulating film is, for example, SiO₂, SiN, or the like.

The material of the first pad 21 is, for example, aluminum (Al). By forming the first pad 21 using aluminum, wire bonding is facilitated. Note that the LDD substrate 4 and the LD chip 5 can be bonded without wire bonding. Wire bonding may be performed when the mounting substrate 2 and the first pad 21 shown in FIG. 1 are connected. Aluminum has high conductivity and excellent contact with a bonding wire.

In addition, when the first pad 21 is formed of aluminum, oxide film passivation is formed on the front surface, and resistance to corrosion or the like can be enhanced. Note that the first pad 21 may be made of metal other than aluminum.

The first pad 21 is for applying a drive signal to the anode electrode 14 of the light emitting element 13 in the LD chip 5. Although not shown in FIG. 9A, the number of first pads 21 corresponding to the number of light emitting elements 13 in the LD chip 5 is formed on the LDD substrate 4.

Next, as shown in FIG. 9B, the insulating film 26 is patterned so that the first pad 21 is exposed. The patterning of the insulating film 26 may be performed by dry etching or wet etching.

Next, as shown in FIG. 9C, the third conductive layer 22 is formed on the first surface S1 of the LDD substrate 4. The third conductive layer 22 functions as a barrier layer for the bonding layer 6. The third conductive layer 22 is formed by laminating a plurality of metal layers. In a case where the first pad 21 is made of aluminum, the lowermost layer of the third conductive layer 22 is desirably a titanium (Ti) layer. Thus, migration of aluminum can be suppressed. For example, a copper (Cu) layer is formed on the Ti layer. The third conductive layer 22 including the laminated film 12 of a Ti layer and a Cu layer functions as a barrier layer (UBM layer: Under Barrier Metal) for the bonding layer 6.

In the third conductive layer 22, a boundary portion between the first pad 21 and the insulating film 26, which is disposed on the upper surface of the first pad 21 and the side surface and the upper surface of the insulating film 26, is a step, and the third conductive layer 22 is formed with a predetermined film thickness so that the third conductive layer 22 is not disconnected at the step portion. More specifically, the film thickness of the third conductive layer 22 depends on the film thickness of the insulating film 26. As the film thickness of the insulating film 26 increases, the film thickness of the third conductive layer 22 also needs to be increased. The Ti layer and the Cu layer constituting the third conductive layer 22 are formed by sputtering, vapor deposition, or the like.

Next, as shown in FIG. 9D, a photoresist 27 is formed on the first surface S1 of the LDD substrate 4, and the photoresist 27 is patterned in a lithography process. Specifically, the photoresist 27 is patterned such that the upper surface of the third conductive layer 22 is exposed. The end surface of the opening formed by patterning of the photoresist 27 may be located outside or inside the step of the third conductive layer 22. The film thickness of the photoresist 27 is set in accordance with the film thickness of the bonding layer 6. For example, in a case where the first pads 21 are formed at a narrow pitch of 20 μm or less, the film thickness of the photoresist 27 is about 3 to 15 μm.

Next, as shown in FIG. 9E, the bonding layer 6 is formed on the third conductive layer 22 in the opening of the photoresist 27. In the present specification, the bonding layer 6 may be referred to as a plating layer or a solder layer. The bonding layer 6 may be formed by an electrolytic plating method or an electroless plating method. The bonding layer 6 is formed by laminating a plurality of metal layers. The material of the bonding layer 6 is, for example, a three-layer structure of Cu pillar/Ni/SnAg. Alternatively, a four-layer structure of Cu/Ni/Cu/SnAg may be used. Alternatively, a two-layer structure of Ni/SnAg may be used. In addition, a laminated film 12 of Cu/Ni/AuSn, Cu/Ni/Cu/AuSn, Ni/AuSn, Cu/Ni/SnBi, Cu/Ni/Cu/SnBi, Ni/SnBi, or the like may be used.

The reason why the Ni layer is sandwiched between the SnAg layer and the Cu layer is that when there is no Ni layer, SnAg and Cu easily react to form an inter metal compound (IMC). The formation of IMC is a factor that lowers reliability. The Ni layer functions as a barrier layer for the SnAg layer and the Cu layer.

The film thickness of each layer constituting the bonding layer 6 is arbitrary, but the film thickness of the Ni layer is desirably set so that the SnAg layer does not diffuse into the underlying Cu layer. For the SnAg layer, the film thickness of the SnAg layer is desirably set so that a sufficient amount of the SnAG layer is also attached to the LD chip 5 side when the LD chip 5 is bonded. As an example, in a case where the bonding layer 6 is Cu/Ni/SnAg, the film thickness of the Cu layer is 1 to 10 μm, the film thickness of the Ni layer is 1 to 8 μm, and the film thickness of the SnAg layer is 1 to 10 μm.

Next, as shown in FIG. 9F, the patterned photoresist 27 is removed by etching or the like.

Next, as shown in FIG. 9G, a part of the third conductive layer 22 is removed. Here, a part of the third conductive layer 22 is removed by, for example, wet etching. For example, in a case where the pitch of the first pads 21 is 20 μm, the diameter of the bonding layer 6 is about 10 μm, and thus it is important to control the undercut amount of the third conductive layer 22. The amount of undercut of the third conductive layer 22 is desirably adjusted by controlling the type of etchant of wet etching and the etching conditions.

Next, as shown in FIG. 9H, a reflow process of the bonding layer 6 is performed. The reflow process may be performed in a state where the flux is formed on the front surface of the bonding layer 6, or the reflow process of the bonding layer 6 may be performed in formic acid. At this time, there is a possibility that wicking occurs in which a solder material such as SnAg goes around the side wall of the Ni layer or the Cu layer. In order to prevent wicking, it is important to control the temperature profile of the reflow process. If the temperature is too high, wicking is likely to occur, and if the temperature is too low, segregation occurs in a solder material such as SnAg, and good bonding cannot be obtained. Both temperature control and time control of reflow are desirably performed.

Through the above processes, the bonding layer 6 subjected to the reflow process is formed on the first pad 21 of the LDD substrate 4. As described in each manufacturing process of FIGS. 9A to 9H, since the first pad 21 on the LDD substrate 4 is formed on a substantially flat surface, the third conductive layer 22 and the bonding layer 6 can be relatively easily formed by normal photolithography or the like.

### Process of Manufacturing LD Chip

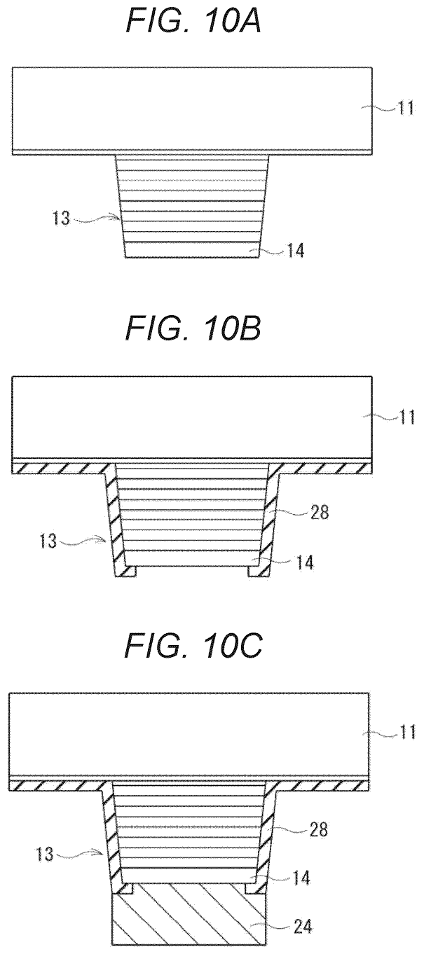

Next, a process of manufacturing the LD chip 5 side will be described. FIGS. 10A to 10C are process cross-sectional views illustrating the process of manufacturing the LD chip 5 according to the present embodiment. As shown in FIG. 10A, a plurality of light emitting elements 13 having a mesa structure is formed on a substrate of the LD chip 5. Each light emitting element 13 is formed of the laminated film 12 as described above. In the process of FIG. 10A, the second pad 14 functioning as the anode electrode 14 is formed on the upper surface of each light emitting element 13 (the bottom surface of the light emitting element 13 of FIG. 10A) when viewed from the substrate side. The second pad 14 is, for example, a laminated film of Ti/Pt/Au. The Ti layer is a barrier layer when connected to the laminated film 12 constituting the light emitting element 13. The Pt layer is a barrier layer for the Au layer. The Au layer functions as an oxidation prevention layer that prevents oxidation of the front surface of the second pad 14. The Ti layer has a film thickness of, for example, 50 to 200 nm. The Pt layer has a film thickness of, for example, 100 to 500 nm. The Au layer has a film thickness of, for example, 50 to 300 nm. The Au layer is effective for suppressing oxidation of the front surface of the first pad 21, but when the Au layer is too thick, Au diffuses into the bonding layer 6 and becomes a factor of voids, so that the film thickness of the Au layer needs to be controlled.

Next, as shown in FIG. 10B, an insulating film 28 is formed on the front surface of the LD chip 5 on the second surface S2 side. The insulating film 28 is, for example, SiN. The film thickness of the insulating film 28 is, for example, about 230 nm. By increasing the film thickness of the insulating film 28 to some extent, it is possible to prevent moisture from entering the LD chip 5 from the outside. Thereafter, an opening is formed in a part of the insulating film 28. The opening can be formed by dry etching or wet etching.

Next, as shown in FIG. 10C, a fourth conductive layer 24 is formed in the opening of insulating film 28. The fourth conductive layer 24 functions as a barrier layer (UBM layer) that prevents diffusion of Au and Pt included in the second pad 14. The fourth conductive layer 24 is, for example, a laminated film of Ni/Au. The Ni layer can prevent diffusion of Au and Pt in the second pad 14. Note that the fourth conductive layer 24 is not an essential layer, and may be omitted.

In a case where the fourth conductive layer 24 is formed of the laminated film 12 of Ni/Au, the film thickness of the Ni layer is, for example, about 500 to 3000 nm, and the film thickness of the Au layer is, for example, about 25 to 300 nm.

The ratio between the size of the second pad 14 and the size of the fourth conductive layer 24 is important. For example, in a case where the fourth conductive layer 24 has a diameter of 10 μm, the bonding layer 6 desirably has a diameter of 8 to 10 μm. That is, the diameter size of the bonding layer 6 is desirably 80 to 100% of the diameter size of the fourth conductive layer 24. As the diameter size of the bonding layer 6 is smaller, the bonding layer 6 spreads toward the second pad 14 and the bonding layer 6 is insufficient, so that there is a possibility that voids are formed in the bonding layer 6.

The manufacturing process of FIGS. 10A to 10C described above is performed in the size of the substrate of the LD chip 5. After the process of FIG. 10C is completed, a process of singulating the LD chip 5 in units of one or a plurality of light emitting elements 13 is performed. Thereafter, a process of bonding each singulated light emitting element 13 to the LDD substrate 4 is performed.

### Process of Bonding Light Emitting Elements 13 to LDD Substrate 4

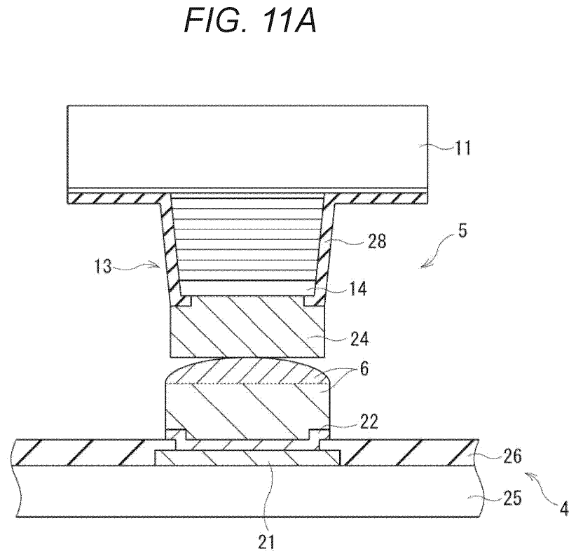

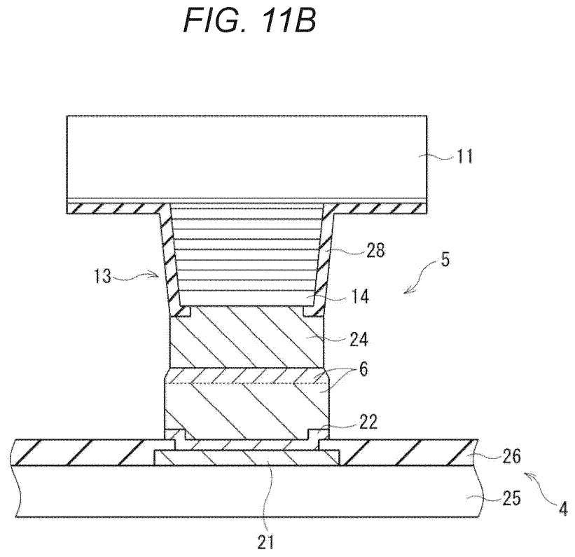

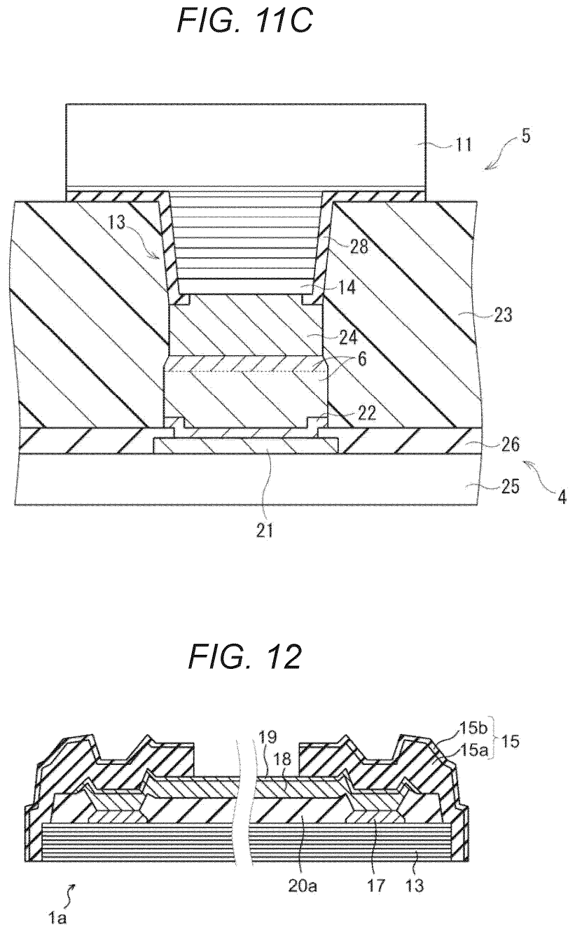

FIGS. 11A to 11C are manufacturing process views illustrating in more detail a process of bonding each singulated light emitting element 13 to the LDD substrate 4. The LDD substrate 4 has a wafer size. On the LD chip 5 side, one or a plurality of light emitting elements 13 are singulated as a unit. Therefore, FIGS. 11A to 11C show that the LD chip 5 is connected to the LDD substrate 4 by chip on wafer (CoW).

First, as shown in FIG. 11A, the singulated light emitting elements 13 are positioned on the LDD substrate 4, and reflow processing is performed. The CoW connection is generally performed by a flip chip bonder, but a desired shape can be obtained even when the CoW connection is performed by a thermo compressive bonder (TCB). In the case of the flip chip bonder, the singulated LD chip 5 is temporarily placed in a state where the flux is formed on the front surface of the LDD substrate 4, and the reflow process shown in FIG. 11B is performed.

There are the following two types of reflow process, and either one may be adopted. In one type, as described above, a reflow process is performed after the flux is formed on the front surface of the LDD substrate 4 in advance. In the other type, a reflow process is performed in formic acid without forming a flux. In the case of the present embodiment, since the diameter size of the bonding layer 6 on the LDD substrate 4 is small, there is a possibility that the solder material in the bonding layer 6 goes around the side wall of the Ni layer or the Cu layer and wicking occurs. To prevent wicking, the temperature profile of the reflow is important. If the temperature is too high, wicking is likely to occur, and if the temperature is too low, segregation occurs in the solder material, and good bonding cannot be obtained. In the reflow process of FIG. 11B, for example, the temperature of the peak region is desirably controlled at 220° C. to 240° C. for about 40 to 70 seconds.

Next, as shown in FIG. 11C, the underfill layer 23 is injected into a gap between the LDD substrate 4 and the LD chip 5. Formation of the underfill layer 23 is an important process for ensuring reliability of connection between the LDD substrate 4 and the LD chip 5. The height on the LD chip 5 side is as thin as about 100 μm, and there is a possibility of bleeding in which the underfill layer 23 creeps up to the substrate side of the LD chip 5. Therefore, selection of the material of the underfill layer 23 and control of the process of injecting the underfill layer 23 are important. As a material of the underfill layer 23, a material having a high glass transition temperature Tg and a curing temperature Tp lower than the glass transition temperature Tg are desirably selected to improve reliability.

When the LD chip 5 is singulated, a process of dicing the substrate is performed. At this time, in blade dicing, the unevenness of the side surface of the divided substrate 11 increases. When the unevenness of the side surface of the substrate 11 is large, there is a possibility that bleeding occurs in which the underfill layer 23 injected into the gap between the LDD substrate 4 and the LD chip 5 crawls up to the side surface of the substrate 11. On the other hand, in stealth dicing, since the substrate 11 is diced by irradiation with a laser beam, the dicing surface of the substrate 11 is flat, and the above-described bleeding hardly occurs. Therefore, when the LD chip 5 is singulated, stealth dicing is desirably performed.

As described above, instead of forming the bonding layer 6 on the upper surface of each light emitting element 13 of the LD chip 5, the bonding layer 6 is formed on the first pad 21 of the LDD substrate 4 and then the LD chip 5 is bonded, so that the formation position shift of the bonding layer 6 is less likely to occur. Each of the light emitting elements 13 of the LD chip 5 is processed into a mesa shape, and it is difficult to accurately form the bonding layer 6 on the upper surface of each of the light emitting elements 13 in a process, and a defect such as a short circuit between the anode electrodes 14 of two adjacent light emitting elements 13 is likely to occur due to a formation position shift of the bonding layer 6. On the other hand, since the periphery of the first pad 21 of the LDD substrate 4 is substantially flat, the bonding layer 6 can be relatively easily formed on the first pad 21. Therefore, the bonding layer 6 can be formed more easily and accurately than forming the bonding layer 6 on the upper surface of each light emitting element 13 of the LD chip 5, and the LDD substrate 4 and the LD chip 5 can be bonded without position shift.

### Second Embodiment

A light emitting device according to a second embodiment has a feature in preventing peeling or the like of a dielectric multilayer mirror disposed on a light emitting element.

FIG. 12 is a cross-sectional view of a light emitting device 1a according to a second embodiment. In the light emitting device 1a of FIG. 12, components common to those in FIG. 4A are denoted by the same reference numerals, and differences will be mainly described below.

The light emitting device 1a of FIG. 12 includes a dielectric multilayer mirror (DMM 20a) 20a laminated on a light emitting element 13. A reflection layer including a single layer may be disposed instead of the DMM 20a.

A contact electrode 17 is laminated on the light emitting element 13 on an outer peripheral side of the DMM 20a. The light emitting element 13 emits light from the lower surface (light emitting surface) of FIG. 12. Therefore, the upper side of FIG. 12 is a surface side opposite to the light emitting surface of the light emitting element 13, and the LDD substrate 4 of FIG. 2 is disposed to face.

A reflection electrode 18 is disposed on the DMM 20a and the contact electrode 17. A pad electrode 19 is disposed on the reflection electrode 18. The outer peripheral side of the pad electrode 19 is covered with an insulating layer 15.

Similarly to FIG. 4A, the insulating layer 15 has, for example, a two-layer structure of a first insulating layer 15a and a second insulating layer 15b.

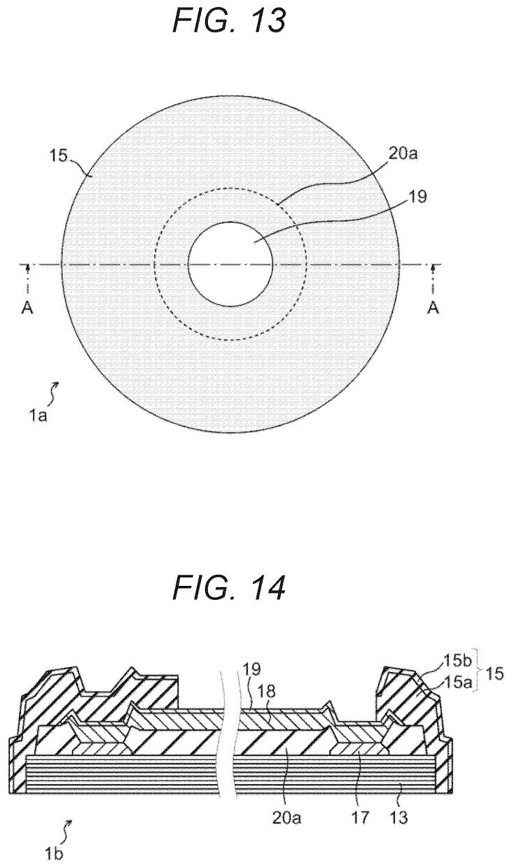

FIG. 13 is a plan view of a surface opposite to the light emitting surface of the light emitting device 1a of FIG. 12 as seen in plan view from a normal direction. FIG. 12 shows a cross-sectional structure taken along line A-A in FIG. 13. As shown in FIGS. 12 and 13, in the light emitting device 1a according to the second embodiment, the insulating layer 15 is disposed so as to overlap at least a part of the DMM 20a. More specifically, in the example of FIG. 13, the insulating layer 15 is disposed so as to overlap the entire region on the outer peripheral side of the DMM 20a. As a result, the adhesion between the DMM 20a and the light emitting element 13 is improved, and a defect that the DMM 20a is unintentionally peeled can be prevented.

The extent to which the insulating layer 15 and the DMM 20a overlap each other is arbitrary. A region that does not overlap the insulating layer 15 may be present on a part of the outer peripheral side of the DMM 20a.

In the plan view of FIG. 13, an example in which the DMM 20a has a substantially annular shape is shown, but a part of the annular shape may be cut.

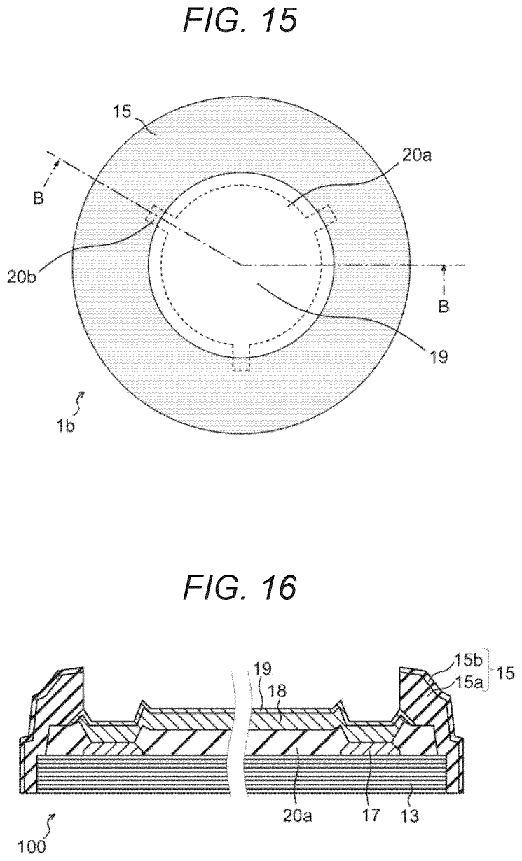

FIG. 14 is a cross-sectional view of a light emitting device 1b according to a modification of the second embodiment, and FIG. 15 is a plan view of the light emitting device 1b according to the modification of the second embodiment. FIG. 14 shows a cross-sectional structure taken along line B-B in FIG. 15.

A DMM 20a in the light emitting device 1b of FIG. 14 has a plurality of protrusions 20b protruding outward from an outer peripheral portion, and an insulating layer 15 is disposed so as to overlap the protrusions 20b. An outer peripheral side of the DMM 20a other than the protrusions 20b is disposed so as not to overlap the insulating layer 15. The number and size of the protrusions 20b are arbitrary.

In the light emitting device 1b having the structure of FIGS. 14 and 15, only a part of the outer peripheral side of the DMM 20a overlaps the insulating layer 15, and by providing the overlapping portion, it is possible to prevent defects such as peeling of the DMM 20a.

FIG. 16 is a cross-sectional view of a light emitting device 100 according to a comparative example. In the comparative example of FIG. 16, an insulating layer 15 is disposed so as not to overlap a DMM 20a when viewed in plan from a normal direction of a surface opposite to a light emitting surface of a light emitting element 13. As a result, the adhesion between the DMM 20a and the light emitting element 13 is lower than that of the light emitting device 1a, 1b of FIGS. 12 to 15, and defects such as peeling of the DMM 20a are likely to occur.

As described above, in the second embodiment, when the light emitting device 1a, 1b is viewed in plan view from the normal direction of the surface opposite to the light emitting surface, the insulating layer 15 is disposed so as to overlap at least a part of the DMM 20a, so that adhesion between the DMM 20a and the light emitting element 13 can be improved, and defects such as peeling of the DMM 20a can be prevented.

The light emitting device 1 (1a, 1b) according to the first or second embodiment can be used, for example, in a distance measuring device (also referred to as a distance measuring module) 40 that measures a distance to an object in a non-contact manner. In the distance measuring device 40, the light emitting signal of the light emitting device 1 (1a, 1b) is reflected by the object, and the light receiving device 41 that receives the reflected light signal is required. The light emitting device 1 (1a, 1b) and the light receiving device 41 may be disposed separately, or may be disposed on a common support member 42.

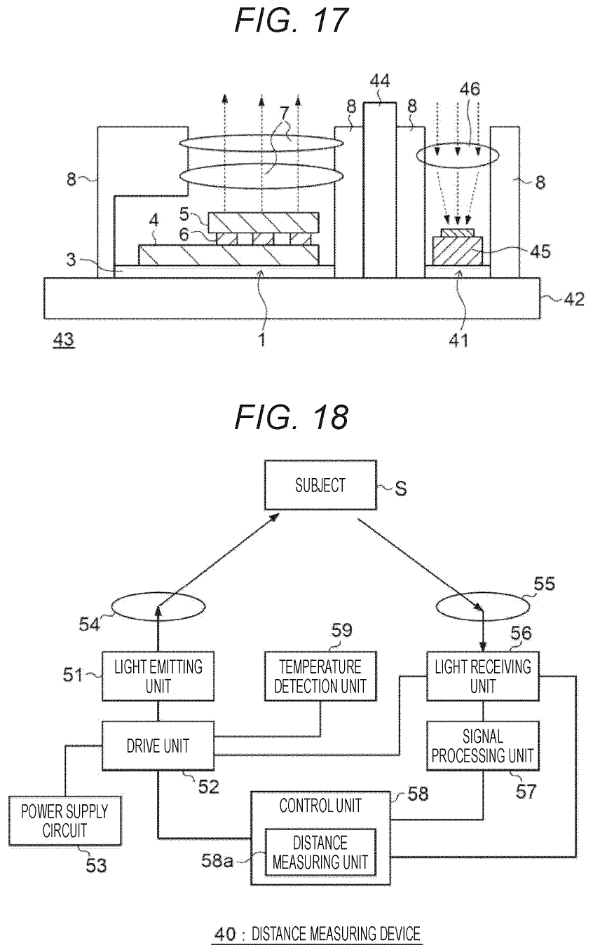

FIG. 17 is a cross-sectional view of a ToF sensor 43 in which the light emitting device 1 and the light receiving device 41 are disposed on the same support member 42. Note that the light emitting device 1a or 1b may be provided instead of the light emitting device 1 of FIG. 17. As shown in FIG. 17, the light emitting device 1 and the light receiving device 41 are supported by the common support member 42, and a light shielding wall 44 is disposed between the light emitting device 1 and the light receiving device 41. Similarly to FIG. 1, the light emitting device 1 of FIG. 17 includes an LDD substrate 4 and an LD chip 5 that are bonded to each other, and a correction lens 7. The light receiving device 41 of FIG. 17 includes a light receiving element 45 and a condenser lens 46. The condenser lens 46 condenses the reflected light signal from the object and forms an image on the light receiving element.

### Configuration of Distance Measuring Device 40

FIG. 18 shows a configuration example of a distance measuring device 40 as an implementation example of the light emitting device 1 (1a, 1b) according to the first or second embodiment.

As shown in the drawing, the distance measuring device 40 includes a light emitting unit 51, a drive unit 52, a power supply circuit 53, a light-emitting side optical system 54, a light-receiving side optical system 55, a light receiving unit 56, a signal processing unit 57, a control unit 58, and a temperature detection unit 59.

The light emitting unit 51 emits light by a plurality of light sources. The light emitting unit 51 and the light-emitting side optical system 54 correspond to the above-described light emitting device 1 (1a, 1b). As will be described later, the light emitting unit 51 of the present example includes a light emitting element 13 by a vertical cavity surface emitting laser (VCSEL) as each light source, and these light emitting elements 13 are arranged in a predetermined mode such as a matrix.

The drive unit 52 includes a power supply circuit 53 for driving the light emitting unit 51. The power supply circuit 53 generates a power supply voltage (drive voltage Vd to be described later) of the drive unit 52 on the basis of, for example, an input voltage (input voltage Vin to be described later) from a battery or the like (not shown) provided in the distance measuring device 40. The drive unit 52 drives the light emitting unit 51 on the basis of the power supply voltage.

The light emitted from the light emitting unit 51 is radiated onto a subject (object) S as a distance measurement target via the light-emitting side optical system 54. Then, the reflected light from the subject S of the light radiated in this manner is incident on the light receiving surface of the light receiving unit 56 via the light-receiving side optical system 55.

The light receiving unit 56 is, for example, a light receiving element such as a charge coupled device (CCD) sensor or a complementary metal oxide semiconductor (CMOS) sensor, receives reflected light from the subject S incident through the light-receiving side optical system 55 as described above, converts the reflected light into an electrical signal, and outputs the electrical signal. The light receiving unit 56 and the light-receiving side optical system 55 correspond to the light receiving device 41 shown in FIG. 17.

The light receiving unit 56 executes, for example, correlated double sampling (CDS) processing, automatic gain control (AGC) processing, or the like on an electrical signal obtained by photoelectrically converting received light, and further performs analog/digital (A/D) conversion processing. Then, the signal as digital data is output to the signal processing unit 57 in the subsequent stage.

Furthermore, the light receiving unit 56 of the present example outputs a frame synchronization signal Fs to the drive unit 52. Thus, the drive unit 52 can cause the light emitting element 13 in the light emitting unit 51 to emit light at timing corresponding to the frame period of the light receiving unit 56.

The signal processing unit 57 is configured as a signal processing processor by, for example, a digital signal processor (DSP) or the like. The signal processing unit 57 performs various types of signal processing on the digital signal input from the light receiving unit 56.

The control unit 58 includes, for example, a microcomputer including a central processing unit (CPU), a read only memory (ROM), a random access memory (RAM), and the like, or an information processing device such as a DSP, and performs control of the drive unit 52 for controlling light emission operation by the light emitting unit 51 and control related to light reception operation by the light receiving unit 56.

The control unit 58 has a function as a distance measuring unit 58a. The distance measuring unit 58a measures the distance to the subject S on the basis of a signal input via the signal processing unit 57 (that is, a signal obtained by receiving reflected light from the subject S). The distance measuring unit 58a of the present example measures a distance to each part of the subject S in order to enable identification of the three-dimensional shape of the subject S.

Here, a specific method for distance measurement in the distance measuring device 40 will be described again later.

The temperature detection unit 59 detects the temperature of the light emitting unit 51. As the temperature detection unit 59, for example, a configuration in which temperature detection is performed using a diode can be adopted.

In the present example, the information about the temperature detected by the temperature detection unit 59 is supplied to the drive unit 52, whereby the drive unit 52 can drive the light emitting unit 51 on the basis of the information about the temperature.

### Distance Measuring Method

As a distance measuring method in the distance measuring device 40, for example, a distance measuring method by a structured light (STL) method or a time of flight (ToF) method can be adopted.

The STL method is a method for measuring a distance on the basis of an image of the subject S irradiated with light having a predetermined light/dark pattern such as a dot pattern or a lattice pattern.

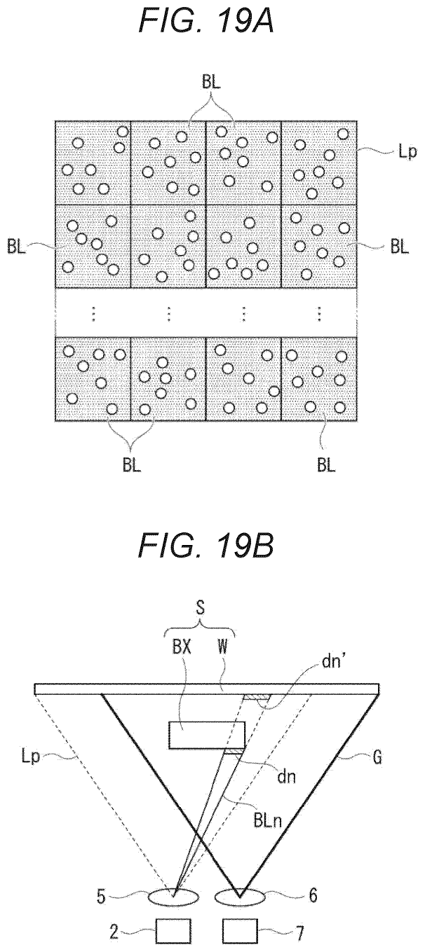

FIG. 19A is an explanatory view of the STL method. In the STL method, for example, the subject S is irradiated with pattern light Lp by a dot pattern as shown in FIG. 19A. The pattern light Lp is divided into a plurality of blocks BL, and different dot patterns are allocated to the respective blocks BL (the dot patterns do not overlap between the blocks B).

FIG. 19B is an explanatory view of the distance measurement principle of the STL method.

Here, an example in which a wall W and a box BX disposed in front of the wall W are the subject S, and the subject S is irradiated with the pattern light Lp is used. “G” in the drawing schematically represents the angle of view by the light receiving unit 56.

In addition, “BLn” in the drawing means light of a certain block BL in the pattern light Lp, and “dn” means a dot pattern of the block BLn projected on the light receiving image by the light receiving unit 56.

Here, in a case where the box BX in front of the wall W does not exist, the dot pattern of the block BLn is projected at the position of “dn′” in the drawing in the light receiving image. That is, the position at which the pattern of the block BLn is projected in the light receiving image is different between the case where the box BX exists and the case where the box BX does not exist, and specifically, the pattern distortion occurs.

The STL method is a method for obtaining the shape and depth of the subject S by using the fact that the pattern irradiated in this manner is distorted by the object shape of the subject S. Specifically, the STL method is a method for obtaining the shape and depth of the subject S from the way of the distortion of the pattern.

In the case of adopting the STL method, for example, an infrared (IR) light receiving unit by a global shutter method is used as the light receiving unit 56. Then, in the case of the STL method, the distance measuring unit 58a controls the drive unit 52 so that the light emitting unit 51 emits pattern light, detects the distortion of the pattern for the image signal obtained via the signal processing unit 57, and calculates the distance on the basis of the way of the distortion of the pattern.

Subsequently, the ToF method is a method for measuring a distance to an object by detecting a flight time (time difference) of light emitted from the light emitting unit 51 until the light is reflected by the object and reaches the light receiving unit 56.

In a case where a so-called direct ToF (dTOF) method is adopted as the ToF method, a single photon avalanche diode (SPAD) is used as the light receiving unit 56, and the light emitting unit 51 is pulse-driven. In this case, the distance measuring unit 58a calculates a time difference between light emission and light reception for light emitted from the light emitting unit 51 and received by the light receiving unit 56 on the basis of a signal input via the signal processing unit 57, and calculates a distance to each unit of the subject S on the basis of the time difference and the speed of light.

Note that, in a case where a so-called indirect ToF (iTOF) method (phase difference method) is adopted as the ToF method, for example, a light receiving unit capable of receiving IR is used as the light receiving unit 56.

### Application Example to Mobile Body

The technology according to the present disclosure (present technology) can be applied to various products. For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a ship, and a robot.

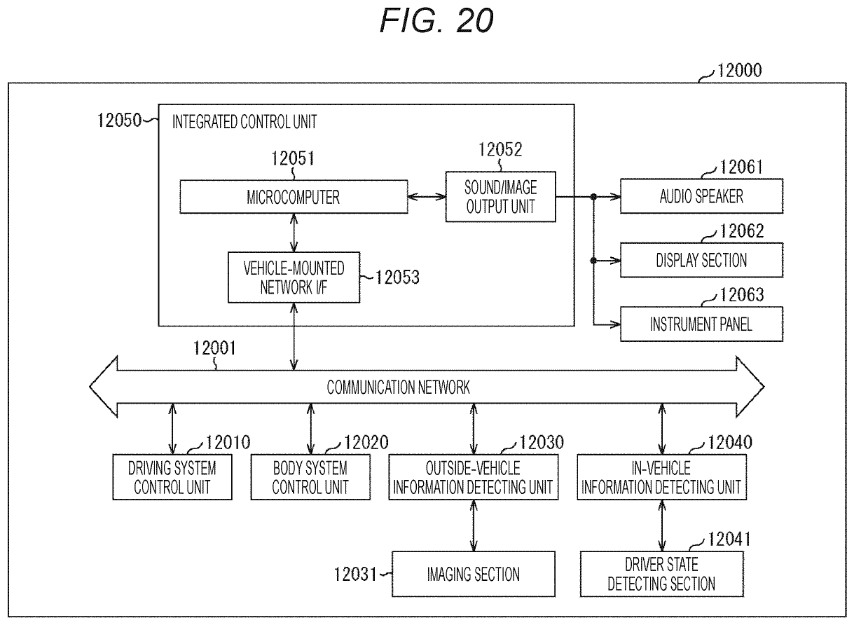

FIG. 20 is a block diagram illustrating a schematic configuration example of a vehicle control system which is an example of a mobile body control system to which the technology according to the present disclosure can be applied.

The vehicle control system 12000 includes a plurality of electronic control units connected to each other via a communication network 12001. In the example shown in FIG. 20, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output unit 12052, and a vehicle-mounted network interface (I/F) 12053 are shown as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are shown as the output device. The display section 12062 may, for example, include at least one of an on-board display and a head-up display.

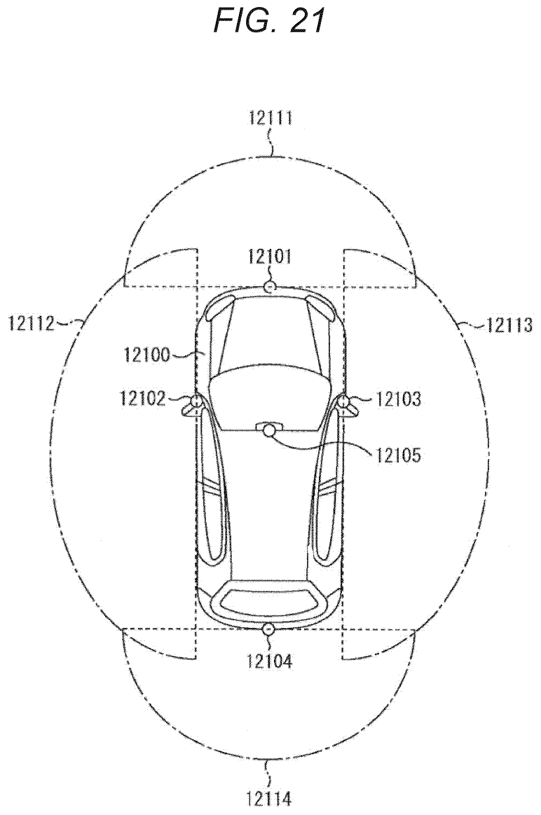

FIG. 21 is a view showing an example of the installation position of the imaging section 12031.

In FIG. 21, the vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided at the side mirrors mainly obtain images of the sides of the vehicle 12100. The imaging section 12104 provided to the rear bumper or the back door obtains mainly an image of the rear of the vehicle 12100. The images of the front of the vehicle obtained by the imaging sections 12101 and 12105 are mainly used for detecting a preceding vehicle, a pedestrian, an obstacle, a traffic light, a traffic sign, a lane, or the like.

Note that, FIG. 21 shows an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031, for example, out of the configurations described above. Specifically, the light emitting device 1 according to the present disclosure may be provided together with the imaging section 12031. By applying the technology according to the present disclosure to the imaging section 12031, it is possible to improve the resolution of the distance image while suppressing the generation of electromagnetic noise, and it is possible to enhance the functionality and safety of the vehicle 12100.

Note that the present technology can have the following configurations.
(1) A light emitting device including:
a first substrate having a light emitting element; and
a second substrate bonded to a surface side opposite to a light emitting surface of the light emitting element,
in which the first substrate includes:
a first conductive layer laminated on the opposite surface side of the light emitting element;
a second conductive layer that is laminated on the first conductive layer and reflects light emitted from the light emitting element to the opposite surface side;
a third conductive layer laminated on the second conductive layer and bonded to the second substrate via a bonding member; and
an insulating layer laminated on the third conductive layer so as to cover at least end portions of the second conductive layer and the third conductive layer laminated.
(2) The light emitting device according to (1), in which the insulating layer is disposed so as to cover at least a part of an upper surface of the third conductive layer from the end portion.
(3) The light emitting device according to (1),
in which a surface of the third conductive layer facing the second substrate includes:
a first region in contact with the bonding member; and
a second region disposed outside the first region and covered with the insulating layer.
(4) The light emitting device according to (3), in which the second region is disposed from a position overlapping the first conductive layer to the end portion when viewed from the lamination direction.
(5) The light emitting device according to (3), in which the second region is disposed from a position closer to a center portion side of a surface of the third conductive layer facing the second substrate than a position overlapping the first conductive layer when viewed from the lamination direction to the end portion.
(6) The light emitting device according to (3), in which a thickness of the insulating layer in the second region is substantially uniform from a center portion side to an end portion side of a surface of the third conductive layer facing the second substrate.
(7) The light emitting device according to (3), in which a thickness of the insulating layer in the second region changes from a center portion side to an end portion side of a surface of the third conductive layer facing the second substrate.
(8) The light emitting device according to (7), in which a thickness of the insulating layer in the second region is thicker on an end portion side than on a center portion side of a surface of the third conductive layer facing the second substrate.
(9) The light emitting device according to any one of (1) to (8), in which the second substrate includes a drive circuit configured to control light emission of the light emitting element.
(10) The light emitting device according to any one of (1) to (9), further including a light receiving unit.
(11) The light emitting device according to any one of (1) to (8), in which the second substrate includes a voltage supply unit configured to supply a predetermined voltage having a fixed voltage level to the light emitting element.
(12) The light emitting device according to any one of (1) to (11),
in which the first conductive layer is disposed in an annular shape so as to surround at least a part of a region through which light emitted by the light emitting element passes,
the second conductive layer is disposed so as to cover an entire region of the first conductive layer including a region through which the light passes, and
the third conductive layer is disposed so as to cover an entire region of the second conductive layer.
(13) The light emitting device according to (12), in which the first conductive layer is interrupted at least at one location in an annular direction.
(14) The light emitting device according to any one of (1) to (13),
in which the light emitting element is a mesa structure, and
the first substrate includes a plurality of the light emitting elements.
(15) The light emitting device according to any one of (1) to (14),
in which the first conductive layer is a contact electrode electrically connected to an electrode on the opposite surface side of the light emitting element,
the second conductive layer is a reflection electrode that reflects light emitted from the light emitting element to the opposite surface side, and
the third conductive layer is a pad electrode that bonds the first substrate to the second substrate via the bonding member.
(16) A light emitting device including:
a first substrate having a light emitting element; and
a second substrate bonded to a surface side opposite to a light emitting surface of the light emitting element,
in which the first substrate includes:
a reflection layer laminated on the opposite surface side of the light emitting element;
a first conductive layer laminated around the reflection layer on the opposite surface side of the light emitting element;
a second conductive layer that is laminated on the reflection layer and the first conductive layer and reflects light emitted from the light emitting element to the opposite surface side;
a third conductive layer laminated on the second conductive layer and bonded to the second substrate via a bonding member; and
an insulating layer laminated on the third conductive layer so as to overlap at least a part of the reflection layer when viewed in plan from a normal direction of the opposite surface of the light emitting element.
(17) The light emitting device according to (16), in which the insulating layer is laminated on the third conductive layer so as to overlap an entire region on an outer peripheral side of the reflection layer when viewed in plan from a normal direction of the opposite surface of the light emitting element.
(18) The light emitting device according to (16),
in which the reflection layer has at least one protrusion protruding outward from an outer peripheral portion of the reflection layer in plan view from a normal direction of the opposite surface of the light emitting element, and
the insulating layer is laminated on the third conductive layer so as to overlap the protrusion when viewed in plan from the normal direction of the opposite surface of the light emitting element.
(19) A distance measuring device including:
a light emitting device including a light emitting element;
a light receiving element; and
a distance measuring unit configured to measure a distance to an object on a basis of a light emitting signal of the light emitting element and a light receiving signal of the light receiving element when the light emitting signal is reflected by the object and received by the light receiving element,
in which the light emitting device includes:
a first substrate including the light emitting element; and
a second substrate bonded to a surface side opposite to a light emitting surface of the light emitting element,
the first substrate includes:
a first conductive layer laminated on the opposite surface side of the light emitting element;
a second conductive layer that is laminated on the first conductive layer and reflects light emitted from the light emitting element to the opposite surface side;
a third conductive layer laminated on the second conductive layer and bonded to the second substrate via a bonding member; and
an insulating layer laminated on the third conductive layer so as to cover at least an end portion of the third conductive layer.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1, 1a, 1b, 100 Light emitting device
2 Mounting substrate
3 Heat dissipation substrate
4 LDD substrate
5 LD chip
6 Bonding layer
7 Correction lens
8 Lens holding portion
11 Substrate
12 Laminated film
13 Light emitting element
14 Anode electrode (second pad)
15 Insulating layer
15a First insulating layer
15b Second insulating layer
16 Cathode electrode
17 Contact electrode
17a Cutout portion
18 Reflection electrode
19 Pad electrode
19a First region
19b Second region
20 Insulating layer
20a DMM
21 First pad
22 Third conductive layer
23 Underfill layer
24 Fourth conductive layer
25 First substrate
26 Insulating film
27 Photoresist
28 Insulating film
31 Crack
32 Gap
40 Distance measuring device
41 Light receiving device
42 Support member
43 ToF sensor
44 Light shielding wall
45 Light receiving element
46 Condenser lens
51 Light emitting unit
52 Drive unit
53 Power supply circuit
54 Light-emitting side optical system
55 Light-receiving side optical system
56 Light receiving unit
57 Signal processing unit
58 Control unit
58a Distance measuring unit
59 Temperature detection unit

1. A light emitting device comprising:
a first substrate having a light emitting element; and
a second substrate bonded to a surface side opposite to a light emitting surface of the light emitting element,
wherein the first substrate includes:
a first conductive layer laminated on the opposite surface side of the light emitting element;
a second conductive layer that is laminated on the first conductive layer and reflects light emitted from the light emitting element to the opposite surface side;
a third conductive layer laminated on the second conductive layer and bonded to the second substrate via a bonding member; and
an insulating layer laminated on the third conductive layer so as to cover at least end portions of the second conductive layer and the third conductive layer laminated.

2. The light emitting device according to claim 1, wherein the insulating layer is disposed so as to cover at least a part of an upper surface of the third conductive layer from the end portion.

3. The light emitting device according to claim 1,
wherein a surface of the third conductive layer facing the second substrate includes:
a first region in contact with the bonding member; and
a second region disposed outside the first region and covered with the insulating layer.

4. The light emitting device according to claim 3, wherein the second region is disposed from a position overlapping the first conductive layer to the end portion when viewed from a lamination direction.

5. The light emitting device according to claim 3, wherein the second region is disposed from a position closer to a center portion side of a surface of the third conductive layer facing the second substrate than a position overlapping the first conductive layer when viewed from the lamination direction to the end portion.

6. The light emitting device according to claim 3, wherein a thickness of the insulating layer in the second region is substantially uniform from a center portion side to an end portion side of a surface of the third conductive layer facing the second substrate.

7. The light emitting device according to claim 3, wherein a thickness of the insulating layer in the second region changes from a center portion side to an end portion side of a surface of the third conductive layer facing the second substrate.

8. The light emitting device according to claim 7, wherein a thickness of the insulating layer in the second region is thicker on an end portion side than on a center portion side of a surface of the third conductive layer facing the second substrate.

9. The light emitting device according to claim 1, wherein the second substrate includes a drive circuit configured to control light emission of the light emitting element.

10. The light emitting device according to claim 1, further comprising a light receiving unit.

11. The light emitting device according to claim 1, wherein the second substrate includes a voltage supply unit configured to supply a predetermined voltage having a fixed voltage level to the light emitting element.

12. The light emitting device according to claim 1,
wherein the first conductive layer is disposed in an annular shape so as to surround at least a part of a region through which light emitted by the light emitting element passes,
the second conductive layer is disposed so as to cover an entire region of the first conductive layer including the region through which the light passes, and
the third conductive layer is disposed so as to cover an entire region of the second conductive layer.

13. The light emitting device according to claim 12, wherein the first conductive layer is interrupted at least at one location in an annular direction.

14. The light emitting device according to claim 1,
wherein the light emitting element is a mesa structure, and
the first substrate includes a plurality of the light emitting elements.

15. The light emitting device according to claim 1,
wherein the first conductive layer is a contact electrode electrically connected to an electrode on the opposite surface side of the light emitting element,
the second conductive layer is a reflection electrode that reflects light emitted from the light emitting element to the opposite surface side, and
the third conductive layer is a pad electrode that bonds the first substrate to the second substrate via the bonding member.

16. A light emitting device comprising:
a first substrate having a light emitting element; and
a second substrate bonded to a surface side opposite to a light emitting surface of the light emitting element,
wherein the first substrate includes:
a reflection layer laminated on the opposite surface side of the light emitting element;
a first conductive layer laminated around the reflection layer on the opposite surface side of the light emitting element;
a second conductive layer that is laminated on the reflection layer and the first conductive layer and reflects light emitted from the light emitting element to the opposite surface side;
a third conductive layer laminated on the second conductive layer and bonded to the second substrate via a bonding member; and
an insulating layer laminated on the third conductive layer so as to overlap at least a part of the reflection layer when viewed in plan from a normal direction of the opposite surface of the light emitting element.

17. The light emitting device according to claim 16, wherein the insulating layer is laminated on the third conductive layer so as to overlap an entire region on an outer peripheral side of the reflection layer when viewed in plan from a normal direction of the opposite surface of the light emitting element.

18. The light emitting device according to claim 16,
wherein the reflection layer has at least one protrusion protruding outward from an outer peripheral portion of the reflection layer when view from a normal direction of the opposite surface of the light emitting element, and
the insulating layer is laminated on the third conductive layer so as to overlap the protrusion when viewed in plan from the normal direction of the opposite surface of the light emitting element.

19. A distance measuring device comprising:
a light emitting device including a light emitting element;
a light receiving element; and
a distance measuring unit configured to measure a distance to an object on a basis of a light emitting signal of the light emitting element and a light receiving signal of the light receiving element when the light emitting signal is reflected by the object and received by the light receiving element,
wherein the light emitting device includes:
a first substrate including the light emitting element; and
a second substrate bonded to a surface side opposite to a light emitting surface of the light emitting element,
the first substrate includes:
a first conductive layer laminated on the opposite surface side of the light emitting element;
a second conductive layer that is laminated on the first conductive layer and reflects light emitted from the light emitting element to the opposite surface side;
a third conductive layer laminated on the second conductive layer and bonded to the second substrate via a bonding member; and
an insulating layer laminated on the third conductive layer so as to cover at least an end portion of the third conductive layer.
